(19) United States
(12) Patent Application Publication
(10) Pub. No.: US 2026/0371651 A1
(43) Pub. Date: Nov. 19, 2026

(54) SEMICONDUCTOR DEVICE WITH INTERVENING LAYER AND METHOD OF FABRICATING THE SAME

(71) Applicant: SAMSUNG ELECTRONICS CO., LTD., Suwon-si (KR)

(72) Inventors: Junseong SONG, Suwon-si (KR); Ryangwoo KIM, Suwon-si (KR); Doosan BACK, Suwon-si (KR); Jung-Hoon HAN, Suwon-si (KR)

(73) Assignee: SAMSUNG ELECTRONICS CO., LTD., Suwon-si (KR)

(21) Appl. No.: 19/421,427

(22) Filed: Dec. 16, 2025

(30) Foreign Application Priority Data
May 15, 2025 (KR) 10-2025-0063281

(51) Int. Cl. H10D 30/67

(52) U.S. Cl. CPC H10D 30/6732; H10D 30/6737

(57) ABSTRACT

A semiconductor device includes a substrate, a gate structure over the substrate, an intervening layer between the gate structure and the substrate, a contact structure spaced apart from the intervening layer and at least partially penetrating an upper portion of the substrate, a metal pattern under the contact structure, and an ohmic pattern at least partially surrounding the metal pattern. The intervening layer and the ohmic pattern are spaced apart from each other. A height of the intervening layer decreases as a distance of the intervening layer from the gate structure increases.

### CROSS-REFERENCE TO RELATED APPLICATIONS

This application claims priority under 35 U.S.C. § 119 to Korean Patent Application No. 10-2025-0063281, filed on May 15, 2025, in the Korean Intellectual Property Office, the disclosures of which are incorporated by reference herein in their entireties.

### BACKGROUND

The present disclosure relates generally to semiconductor devices, and more particularly, to a semiconductor device with an intervening layer and a method of fabricating the same.

Semiconductor devices may be featured as a potentially important factor in the electronics industry due at least in part to characteristics of such devices, which may include, but not be limited to, miniaturization, multi-functionalization, low manufacturing cost, or the like. Semiconductor elements may be classified into a semiconductor storage element that may store logic data, a semiconductor logic element that may arithmetically process logic data, a hybrid semiconductor element that includes a storage element and a logic element, or the like.

Recently, commensurate with increases in processing speeds and/or decreases in power consumption of electronic devices, a semiconductor element incorporated therein may also need to provide a relatively high operating speed and/or a relatively low operating voltage. Attempts to address these needs may include increasing integration levels of the semiconductor devices. However, as the integration levels of a semiconductor device increases, reliability and/or electrical characteristics of the semiconductor device may also decrease.

### SUMMARY

According to an aspect of the present disclosure, a semiconductor device includes a substrate, a gate structure over the substrate, an intervening layer between the gate structure and the substrate, a contact structure spaced apart from the intervening layer and at least partially penetrating an upper portion of the substrate, a metal pattern under the contact structure, and an ohmic pattern at least partially surrounding the metal pattern. The intervening layer and the ohmic pattern are spaced apart from each other. A height of the intervening layer decreases as a distance of the intervening layer from the gate structure increases.

According to an aspect of the present disclosure, a semiconductor device includes a substrate, a gate structure over the substrate, an intervening layer interposed between the gate structure and the substrate, a contact structure spaced apart from the intervening layer and at least partially penetrating an upper portion of the substrate, a metal pattern under the contact structure, and an ohmic pattern at least partially surrounding the metal pattern. The intervening layer and the ohmic pattern are spaced apart from each other. An upper surface of the substrate includes a curved surface. An upper surface of the intervening layer includes another curved surface.

According to an aspect of the present disclosure, a semiconductor device includes a substrate including an active region, a gate structure on the active region, an intervening layer interposed between the gate structure and the substrate, a contact structure spaced apart from the intervening layer and at least partially penetrating an upper portion of the substrate, a metal pattern under the contact structure, and an ohmic pattern at least partially surrounding the metal pattern. The gate structure includes a first gate capping pattern, a gate electrode on the first gate capping pattern, and a second gate capping pattern on the gate electrode. The intervening layer and the ohmic pattern are spaced apart from each other. An upper surface of the substrate includes a curved surface. An upper surface of the intervening layer includes another curved surface.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a cross-sectional view of a semiconductor device, according to some embodiments of the present disclosure;

FIGS. 2, 3A, 3B, and 4 to 6 are cross-sectional views illustrating a method of manufacturing a semiconductor device, according to embodiments of the present disclosure;

FIG. 7 is a plan view of a semiconductor apparatus to which a semiconductor device, according to some embodiments of the present disclosure, is applied;

FIG. 8 is a cross-sectional view according to A1–A1' of FIG. 7, according to some embodiments of the present disclosure; and

FIG. 9 is a cross-sectional view according to B1–B1' of FIG. 7, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlO”, “BaSrTiO”, “BaTiO”, “Co-Si”, “HfO”, “HfSiON”, “HfTaO”, “HfZrO”, “LaO”, “LiO”, “PbScTaO”, “PbZnNb”, “SiCN”, “SiCON”, “SiGe”, “SiN”, “SiO”, “SiON”, “SrAlO”, “TaO₂”, “TiN”, “TiO₂”, “ZrO₂”, “ZrSiO₂”, or the like may refer to a material made of elements included in each of the terms and is not a chemical formula representing a stoichiometric relationship.

Hereinafter, various embodiments of the present disclosure are described with reference to the accompanying drawings.

FIG. 1 is a cross-sectional view of a semiconductor device, according to some embodiments of the present disclosure.

Referring to FIG. 1, the semiconductor device may include a substrate SB. The substrate SB may have a shape extending along a first direction D1 and a second direction D2 intersecting the first direction D1.

The substrate SB may be and/or may include a single crystal silicon substrate. Alternatively or additionally, the substrate SB may be and/or may include a silicon on insulator (SOI) substrate. The substrate SB may be and/or may include a substrate of an epitaxial thin layer obtained by performing selective epitaxial growth (SEG). The substrate SB may be and/or may include a polysilicon doped or undoped with impurities. In an embodiment, the substrate SB may include an n-type or p-type well impurity layer.

An upper surface SB_T of the substrate SB may have a curved surface. The upper surface SB_T of the substrate SB may have a convex curved surface protruding toward a gate structure GST. The substrate SB may have a convex shape toward a third direction D3 perpendicular to the first direction D1 and the second direction D2.

The gate structure GST may be disposed over the substrate SB. The gate structure GST may be disposed on an intervening layer 13. The gate structure GST may be disposed on an uppermost protruding portion of the substrate SB in the third direction D3. A level of the upper surface of the substrate SB on which the gate structure GST is disposed may be the highest among levels of the upper surface of the substrate SB. An area of a lower surface of the gate structure GST in contact with the intervening layer 13 may be smaller than an area of an upper surface 13_T of the intervening layers 13. The area of the upper surface 13_T of the intervening layer 13 may be larger than the area of the lower surface of the gate structure GST.

The gate structure GST may include a gate electrode GE, a gate spacer GS1, a first gate capping pattern GC1, and a second gate capping pattern GC2. The gate structure GST may be interposed between source/drain patterns. With the gate structure GST at the center, the substrate that does not overlap with the gate structure GST may be doped. The doped substrate without overlapping with the gate structure GST may be referred to as the source/drain pattern.

The first gate capping pattern GC1 may be disposed on the intervening layer 13. The first gate capping pattern GC1 may cover the upper surface 13_T of the intervening layer 13.

The first gate capping pattern GC1 may include, for example, a silicon oxide (SiO) layer, a silicon oxynitride (SiON) layer, a high dielectric layer, or the like. For example, the first gate capping pattern GC1 may have a structure in which a silicon oxide (SiO) layer and a high dielectric layer are stacked. The high dielectric layer may include a high dielectric material having a higher dielectric constant than that of the silicon oxide (SiO) layer. For example, the high dielectric constant material may include, but not be limited to, at least one of hafnium oxide (HfO), hafnium silicon oxide (HfSiO), hafnium zirconium oxide (HfZrO), hafnium tantalum oxide (HfTaO), lanthanum oxide (LaO), zirconium dioxide (ZrO₂), zirconium silicon dioxide (ZrSiO₂), tantalum dioxide (TaO₂), titanium dioxide (TiO₂), barium strontium titanium oxide (BaSrTiO), barium titanium oxide (BaTiO), strontium aluminum oxide (SrAlO), lithium oxide (LiO), aluminum oxide (AlO), lead scandium tantalum oxide (PbScTaO), lead zinc niobate (PbZnNb), or the like.

The gate electrode GE may be disposed on the first gate capping pattern GC1. The gate electrode GE may include a metal material.

A pair of gate spacers GS may be disposed on both sidewalls of the gate electrodes GE, respectively. The gate spacers GS may be formed to cover the sidewall of the gate electrode GE. The gate spacers GS may have a shape extending in the third direction D3. an upper surface of each of the gate spacers GS may be higher than an upper surface of the gate electrode GE. The upper surface of each of the gate spacers GS may be coplanar with an upper surface of the second gate capping pattern GC2. For example, the gate spacers GS may include at least one of silicon carbon nitride (SiCN), silicon oxycarbonitride (SiCON), or silicon nitride (SiN). As another example, the gate spacers GS may include a multi-layer composed of at least two of silicon carbon nitride (SiCN), silicon oxycarbonitride (SiCON), silicon nitride (SiN), or the like. As another example, the gate spacers GS may include a silicon (Si)-containing insulating material.

The second gate capping pattern GC2 may be provided on the gate electrode GE. The second gate capping pattern GC2 may be provided to cover the gate electrode GE. For example, the second gate capping pattern GC2 may include at least one of silicon oxynitride (SiON), silicon carbon nitride (SiCN), silicon oxycarbonitride (SiCON), silicon nitride (SiN), or the like.

The intervening layer 13 may be disposed between the gate structure GST and the substrate SB. The intervening layer 13 may be provided on the upper surface SB_T of the substrate SB. The intervening layer 13 may be provided to cover a portion of the upper surface SB_T of the substrate SB and expose a portion of the upper surface SB_ T of the substrate SB. The intervening layer 13 may include silicon germanium (SiGe).

When the intervening layer 13 is formed on the upper surface SB_T of the substrate SB, a formation rate may be different depending on a plane direction. Accordingly, a height of the intervening layer 13 may decrease as the distance from the gate structure GST increases. That is, the height of the intervening layer 13, which may refer to as a vertical distance in the third direction D3 of the intervening layer 13, may have a profile that is greatest (e.g., tallest) at a top of the substrate SB and decreases as the distance from the top of the substrate SB increases.

When the intervening layer 13 is formed on the upper surface SB_T of the substrate SB, since the intervening layers 13 are formed along the upper surface SB_T of the substrate SB, the upper surface 13_T of the intervening layer 13 may include a curved surface. The upper surface 13_T of the intervening layer 13 may have a convex curved surface protruding toward the third direction D3. A radius of curvature of the upper surface 13_T of the intervening layer 13 may be smaller than a radius of curvature of a lower surface of the intervening layer 13.

An insulating layer 16 may be provided on the substrate SB, the intervening layer 13, and the gate structure GST. The insulating layer 16 may cover the gate structure GST. The insulating layer 16 may cover the intervening layer 13. The insulating layer 16 may include an insulating material. The insulating layer 16 may include, for example, a silicon oxide (SiO) layer.

A contact structure CS that is spaced apart from the intervening layer 13 and penetrates a part of the substrate SB and the insulating layer 16 may be provided. The contact structure CS may be provided in a trench TR1 penetrating a portion of the substrate SB and the insulating layer 16. The contact structure CS may be provided to penetrate a region of the upper surface SB_T of the substrate SB not covered with the intervening layer 13. The contact structure CS may be provided to penetrate the upper surface SB_T of the exposed substrate SB. The contact structure CS may be spaced apart from the intervening layer 13. A sidewall of the contact structure CS may be in contact with the substrate SB and the insulating layer 16.

The contact structure CS may include a contact liner 17 and a contact metal 12 on the contact liner 17. The contact liner 17 may be formed to conformally cover a sidewall of the trench TR1. The contact liner 17 may be provided along the sidewall of the trench TR1, and the contact liner 17 may be provided to fill only a portion of the trench TR1. The contact liner 17 may include titanium (Ti). The contact liner 17 may include titanium nitride (TiN).

The contact metal 12 may be formed on the contact liner 17. The contact metal 12 may include a conductive material. The contact metal 12 may include a metal. The contact liner 17 may be interposed between the sidewall of the contact metal 12 and the substrate SB, and between the contact metal 12, and the insulating layer 16.

The contact structure CS may electrically connect the substrate SB and metal wirings. For example, the source/drain patterns of the substrate SB and the metal wirings formed by a back end of line (BEOL) may be electrically connected by the contact structure CS.

A metal pattern 11 may be provided under the contact structure CS. An ohmic pattern 111 surrounding the metal pattern 11 may be provided under the contact structure CS. The metal pattern 11 may include a metal. The metal pattern 11 may include, for example, at least one of cobalt (Co), nickel (Ni), titanium (Ti), or the like. The metal pattern 11 may be in contact with the contact metal 12. The sidewall of the contact metal 12 may be in contact with the contact liner 17, and the lower surface of the contact metal 12 may be in contact to the metal pattern 11. The level of a bottom of the gate structure may be higher than the level of a top of the metal pattern 11.

An ohmic pattern 111 may be provided below the metal pattern 11. The ohmic pattern 111 may have a shape surrounding the contact structure CS. The ohmic pattern 111 may have a shape surrounding the metal pattern 11. The ohmic pattern 111 may be in contact with the metal pattern 11.

The ohmic pattern 111 may include the same metal as the metal pattern 11. The ohmic pattern 111 may include a silicide side. For example, when the metal pattern 11 includes cobalt (Co), the ohmic pattern 111 may include cobalt silicide (Co-Si). The ohmic pattern 111 may be formed between the metal pattern 11 and the substrate SB. For example, the ohmic pattern 111 may be formed as an interface between the metal pattern 11 and the substrate SB is diffused.

The ohmic pattern 111 may be spaced apart from the intervening layer 13. The metal pattern 11 may be spaced apart from the intervening layer 13. A cross-sectional area of the metal pattern 11 may be smaller than a cross-sectional area of the ohmic pattern 111. A cross-sectional area of a plane defined by the first direction D1 and the third direction D3 of the metal pattern 11 may be smaller than a cross-sectional area of a plane defined by the first direction D1 and third direction D3 of the ohmic pattern 111.

In the semiconductor device, according to embodiments of the present disclosure, the contact structure CS, the ohmic pattern 111, and the metal pattern 11 may be spaced apart from the intervening layer 13. The intervening layer 13 may be interposed between the substrate SB and the gate structure GST. Accordingly, the electrical characteristics of the semiconductor device may be improved and the reliability may be improved, when compared to a related semiconductor device.

As the intervening layer 13, which may include silicon germanium (SiGe), is interposed between the substrate SB and the gate structure GST, electrical characteristics of the semiconductor device may be improved, when compared to related semiconductor devices. For example, as the intervening layer 13 is interposed between the substrate SB and the gate structure GST in a PMOSFET, a compressive stress may be formed, and a mobility of holes may be increased, when compared to related semiconductor devices.

As the intervening layer 13 is spaced apart from the substrate SB, the contact structure CS, and the metal pattern 11, the ohmic pattern 111 may not be overgrown. Consequently, gate oxide breakdown may be prevented and/or reduced, and electrical connection between the gate and the contact may be prevented and/or reduced, when compared to related semiconductor devices.

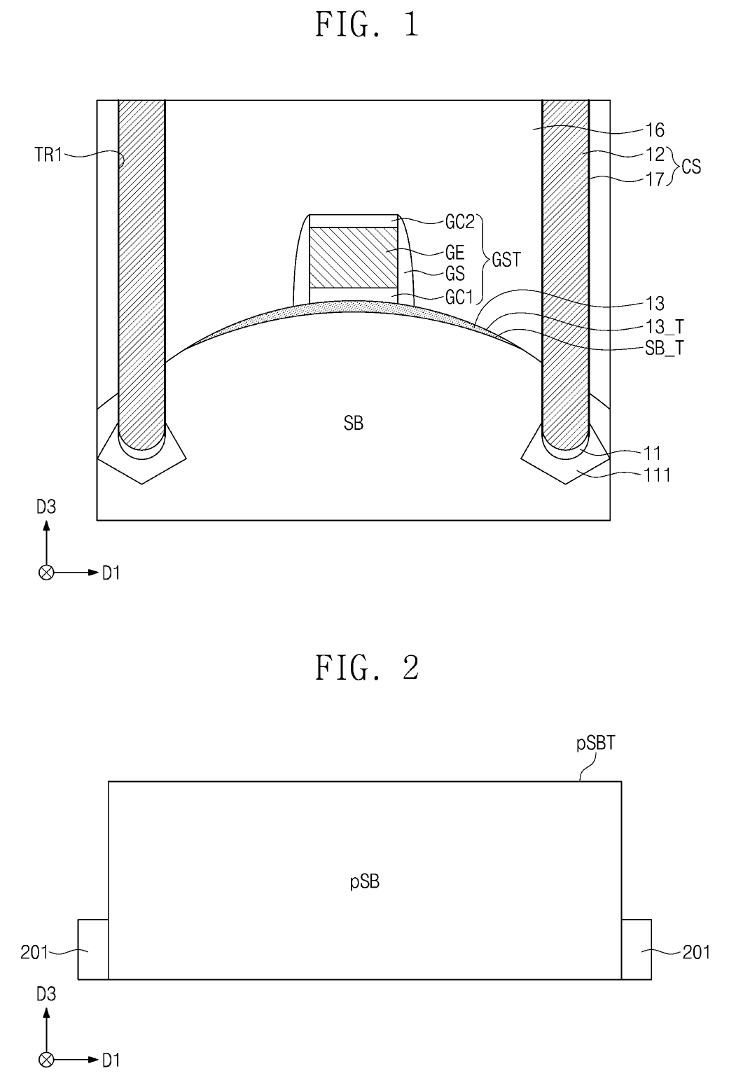

FIGS. 2, 3A, 3B and 4-6, are cross-sectional views illustrating a method of manufacturing a semiconductor device, according to embodiments of the present disclosure.

Referring to FIG. 2, a preliminary substrate pSB may be provided. The preliminary substrate pSB may be provided between a plurality of guide bodies 201. The preliminary substrate pSB may be provided between the plurality of guide bodies 201 spaced apart from each other. One sidewall of the preliminary substrate pSB may be in contact with one guide body 201, and the other sidewall of the pre-substrate pSB may also be in contact with the other guide body 201. A level of an upper surface pSBT of the preliminary substrate pSB may be higher than that of an upper surface of the guide body 201. The upper surface pSBT of the preliminary substrate pSB may have a (100) orientation. The guide body 201 may include, but is not limited to, a silicon oxide (SiO) layer, a silicon nitride (SiN) layer, or the like. In the present disclosure, the “orientation” of a surface refers to a crystallographic plane orientation, which is represented by a Miller index (hkl). For example, the “(100)” orientation indicates that the surface is aligned with a (100) crystal plane. In addition, parentheses “( )” denote crystal planes.

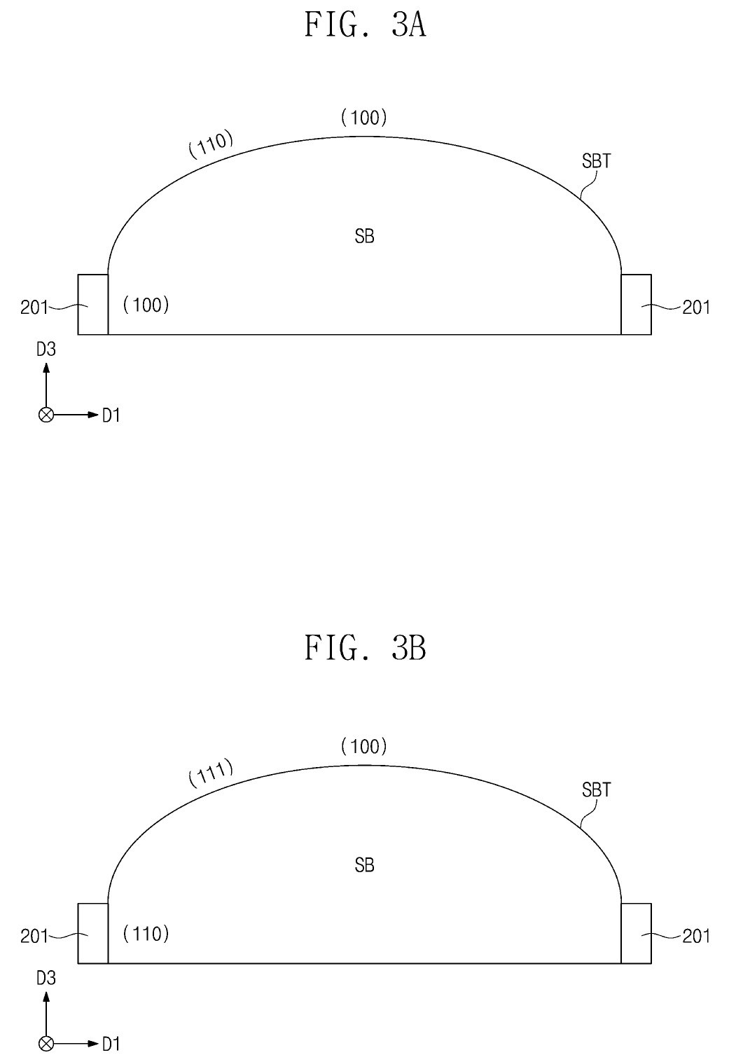

Referring to FIG. 3A, a substrate SB, according to an embodiment of the present disclosure, may be formed. The substrate SB may be formed by epitaxially growing the preliminary substrate pSB. The substrate SB may be formed by baking the preliminary substrate pSB in a hydrogen (H₂) atmosphere. The substrate SB may be formed by heat-treating the preliminary substrate pSB in a hydrogen (H₂) atmosphere. The substrate SB may be formed such that an upper surface SBT has a convex curved surface. In the substrate SB described with reference to FIG. 3A, a (100) plane of the substrate SB may have the highest growth rate, and a (110) plane of the substrate SB adjacent to the guide body 201 may have a slower growth rate. Since the substrate SB includes silicon, a surface free energy of the substrate SB may be greatest in the (100) plane, and may be relatively low for the (110) plane or a (111) plane. The growth rate of the substrate SB may be greatest for a perpendicular direction to the (100) plane, and may be relatively low in a perpendicular direction to the (110) plane or in a perpendicular direction to the (111) plane.

Referring to FIG. 3B, a substrate SB according to an embodiment of present disclosure, may be formed. The description mainly addresses differences from the substrate SB with reference to FIG. 3A.

Unlike the substrate SB with reference to FIG. 3A, in the substrate SB of as shown in FIG. 3B, a (100) plane of the substrate SB may have the greatest growth rate, and a (111) plane adjacent to the guide body 201 may have a slower growth rate. Accordingly, the substrate SB may be formed to have a convex shape protruding in the direction perpendicular to the (100) plane. The upper surface SBT of the substrate SB may be formed to have a curved surface.

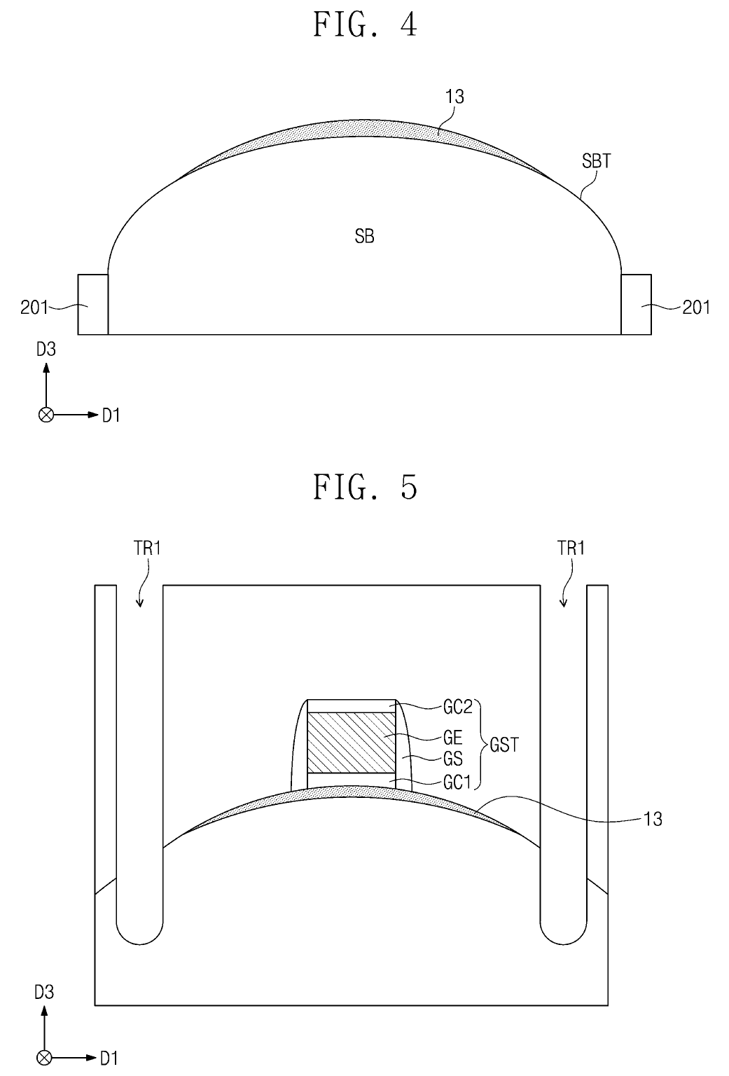

Referring to FIG. 4, an intervening layer 13 may be formed on the upper surface SBT of the substrate SB. The intervening layer 13 may be formed by epitaxially growing silicon germanium (SiGe) on the upper surface SBT of the substrate SB. Since the (100) plane of the upper surface SBT of the substrate SB may have a more protruded curved surface, the intervening layer 13 may also grow at a higher speed in the direction perpendicular to the (100) plane. The upper surface of the intervening layer 13 may include a curved surface.

A thickness of the intervening layer 13 may be greatest in the direction perpendicular to the (100) plane and may decrease toward the direction perpendicular to (110) plane or the direction perpendicular to (111) plane, i.e., (e.g., as a distance to the guide body 201 decreases). In an embodiment, the intervening layer 13 may not be formed on the upper surface SBT of the substrate SB closest to the guide body 201. That is, the upper surface SBT of the substrate SB adjacent to the guide body 201 may be exposed. The intervening layer 13 may be formed to cover only a part of the upper surface SBT of the substrate SB.

Referring to FIG. 5, the guide body 201 may be removed. A gate structure GST may be formed on the intervening layer 13. The gate structure GST may be formed to overlap the (100) surface of the substrate SB.

The insulating layer 16 may be formed to cover the gate structure GST, the intervening layer 13, and the upper surface SBT of the substrate SB.

A trench TR1 may be formed to penetrate a portion of the substrate SB and the insulating layer 16. The trench TR1 may be formed to penetrate the upper surface SBT of the exposed substrate SB. The trench TR1 may be spaced apart from the intervening layer 13. The trench TR1 may not penetrate the intervening layer 13. The trench TR1 may be defined by the insulating layer 16 and the substrate SB.

A plurality of trenches TR1 may be formed. The trench TR1 may be formed to overlap a portion corresponding to a doped source/drain pattern of the substrate SB in the third direction D3, for example.

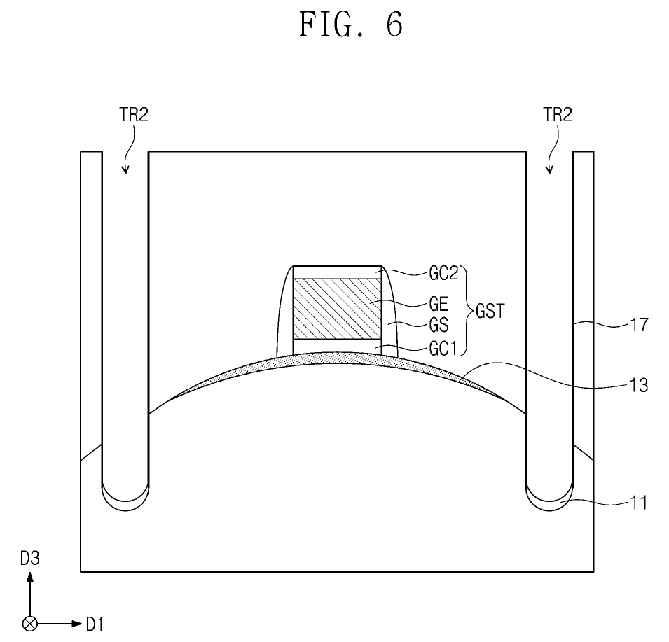

Referring to FIG. 6, a contact liner 17 may be formed along a sidewall of the trench TR1, and a metal pattern 11 may be formed under the trench TR1.

Forming the contact liner 17 and the metal pattern 11 may include forming the contact liner 17 along an inner wall of trench TR1, removing the contact liner 17 under the trench TR1, and then forming the metal pattern 11 under the trench TR1.

Referring again to FIG. 1, the metal pattern 11 may react with an interface of the substrate SB to form an ohmic pattern 111. Forming the ohmic pattern 111 may include heat-treating the substrate SB and the metal pattern 11 to form the ohmic pattern 111. Forming the ohmic pattern 111 may include heat treating at 800 degrees Celsius or less. However, embodiments of the present disclosure are not limited in this regard.

After the ohmic pattern 111 is formed, the contact metal 12 may be formed on the contact liner 17 and the metal pattern 11. Forming the contact metal 12 may include filling an exposed portion of the trench TR1. Forming the contact metal 12 may include filling the trench TR1 not filled with the contact liner 17 and the metal pattern 11 with a conductive material. The semiconductor device of FIG. 1 may be formed in such a manner as described above with reference to FIGS. 2, 3A, 3B and 4-6.

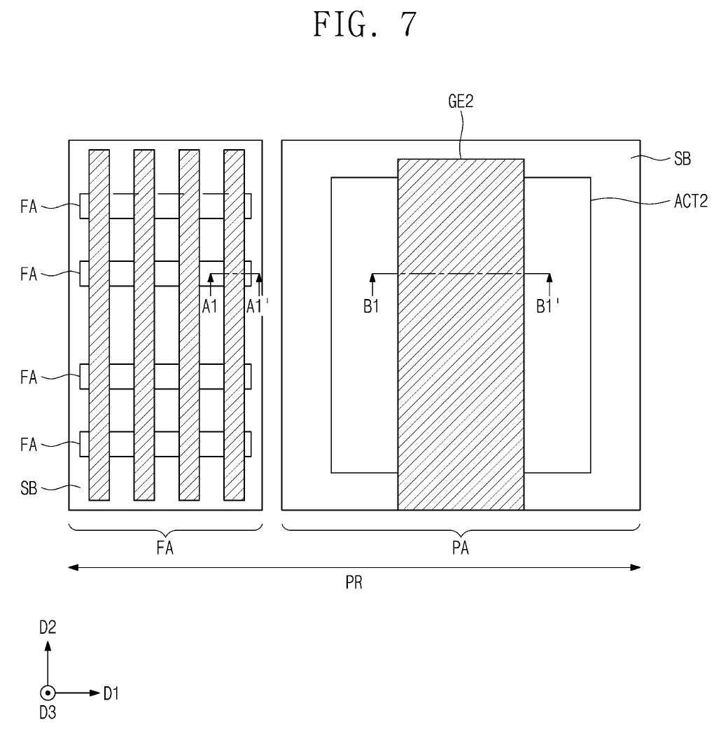

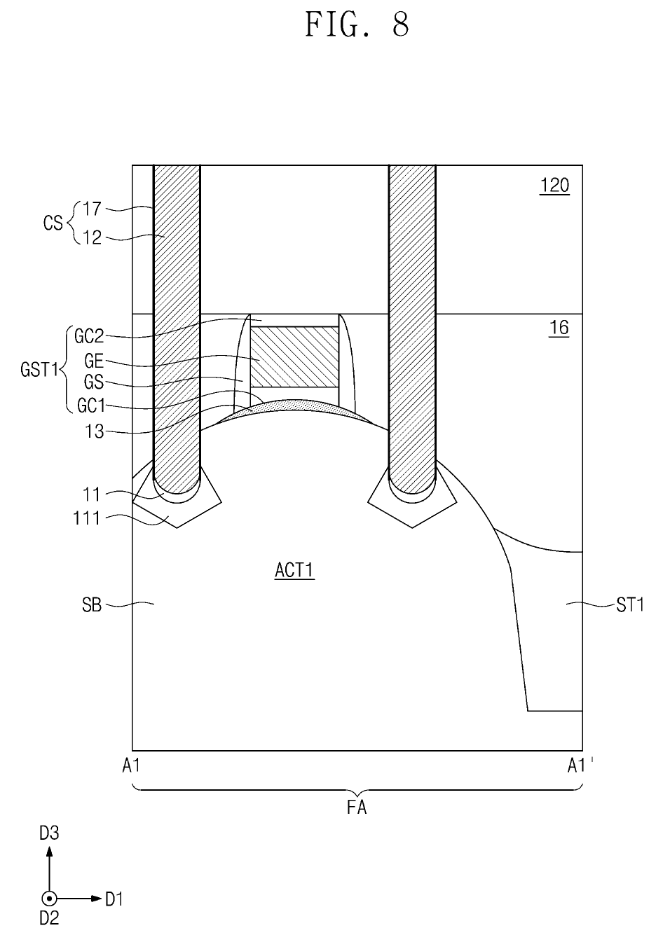

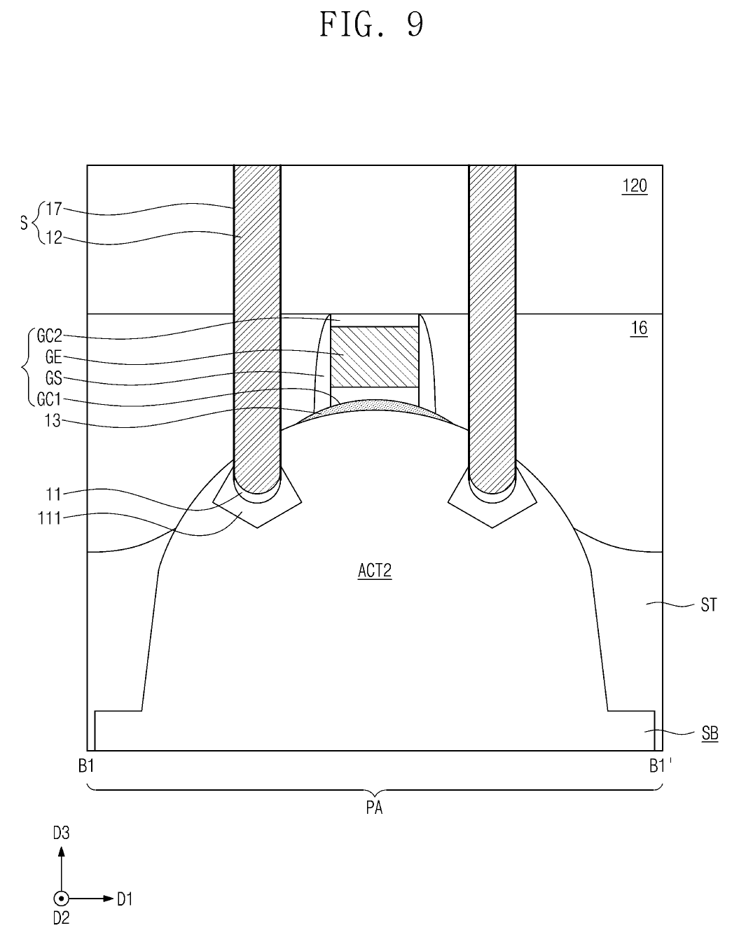

FIG. 7 is a plan view of a semiconductor apparatus to which a semiconductor device, according to some embodiments of the present disclosure, is applied. FIG. 8 is a cross-sectional view according to A1–A1' of FIG. 7, according to some embodiments of the present disclosure. FIG. 9 is a cross-sectional view according to B1–B1' of FIG. 7, according to some embodiments of the present disclosure.

The semiconductor device that has been applied to the semiconductor apparatus of FIGS. 7 to 8 may include and/or may be similar in many respects to the semiconductor device described above with reference to FIG. 1, and may include additional features not mentioned above. Consequently, repeated descriptions of the semiconductor device of FIGS. 7 to 8 described above with reference to FIG. 1 may be omitted for the sake of brevity.

Referring to FIGS. 7 to 9, a substrate SB including a first peripheral region FA and a second peripheral region PA may be provided. Each of the first peripheral region FA and the second peripheral region PA may include and/or may be similar in many respects to a region of the substrate SB provided in FIG. 1, and may include additional features not mentioned above.

A first active pattern ACT1 may be provided on the first peripheral region FA. The first active pattern ACT1 may extend on the substrate SB in a third direction D3, which is a direction perpendicular to an upper surface of the substrate SB. The first active pattern ACT1 may be a portion of the substrate SB.

A first device isolation layer ST1 may be provided on the first peripheral region FA. The first device isolation layer ST1 may define the first active pattern ACT1. The first device isolation layer ST1 may cover a side surface of the first active pattern ACT1. The first device isolation layer ST1 may include, but not be limited to, a silicon oxide (SiO) layer, a silicon nitride (SiN) layer, or the like.

The first active pattern ACT1 of the substrate SB may be electrically connected to the ohmic pattern 111, the metal pattern 11, and the contact structure CS. The ohmic pattern 111, the metal pattern 11, and the contact structure CS may be spaced apart from the intervening layer 13. A first gate structure GST1 may be disposed on the intervening layer 13. The first gate structure GST1 may include and/or may be similar in many respects to the gate structure GST described above with reference to FIG. 1, and may include additional features not mentioned above.

A second active pattern ACT2 may be provided on the second peripheral region PA. The second active pattern ACT2 may extend in the third direction D3 on the upper surface of the substrate SB. The second active pattern ACT2 may be a portion of the substrate SB. The upper surface of the second active pattern ACT2 may have a curved surface.

The second device isolation layer ST2 may cover a side surface of the second active pattern ACT2. The second device isolation layer ST2 may define a second active pattern ACT2.

An intervening layer 13 may be disposed on the second active pattern ACT2. The second gate structure GST2 may be disposed on the intervening layer 13. The ohmic pattern 111, the metal pattern 11, and the contact structure CS may be disposed to be spaced apart from the intervening layer 13. The second gate structure GST2 may include and/or may be similar in many respects to the gate structure GST described above with reference to FIG. 1, and may include additional features not mentioned above.

The insulating layer 16 may be disposed to surround the first gate structure GST1 and the second gate structure GST2 and may cover the first active pattern ACT1 and the second active pattern ACT2. The level of an upper surface of the insulating layer 16 may be substantially similar to and/or the same level as the level of upper surfaces of the first gate structure GST1 and the second gate structure GST2. A molding layer 120 may be disposed on the insulating layer 16. The molding layer 120 may include an insulating material. The contact structure CS may penetrate the molding layer 120.

According to embodiments of the present disclosure, the upper surface of the substrate of the semiconductor device may include a curved surface. The intervening layer including silicon germanium (SiGe) may be disposed between the gate structure and the substrate. Contacts penetrating the substrate of the semiconductor device and the intervening layer may be spaced apart. The contact may connect the substrate and the metal wiring. The ohmic pattern including a metal silicide may be disposed between the contact and the substrate. Accordingly, the ohmic pattern may not be overgrown, and electrical characteristics may be improved, when compared to related semiconductor devices.

That is, the semiconductor device, according to embodiments of the present disclosure, may include the ohmic pattern under the contact connecting the source/drain patterns and the metal wiring of the semiconductor device. The ohmic pattern may include a metal silicide. The contact and the ohmic pattern may be spaced apart from the intervening layer, such that the ohmic pattern may be grown to an appropriate degree. Thereby, a current flow may be smooth, when compared to a related semiconductor device.

A method of manufacturing a semiconductor device, according to an example embodiments of the present disclosure, may include disposing a preliminary substrate between adjacently spaced guide bodies, growing the preliminary substrate to form a substrate having a curved upper surface, forming an intervening layer on the upper surface of the substrate, forming a gate structure on the intervening layer, forming a trench penetrating a portion of the substrate, and forming a contact structure to fill the trench.

In the method of manufacturing the semiconductor device, the forming of the substrate may include performing a heat treatment on the preliminary substrate in a hydrogen (H₂) atmosphere.

In the method of manufacturing the semiconductor device, the forming of the substrate may include adjusting a planar growth rate of the preliminary substrate.

In the method of manufacturing the semiconductor device, the forming of the intervening layer may include growing silicon germanium (SiGe) in a direction perpendicular to a first plane of the substrate.

In the method of manufacturing the semiconductor device, the forming of the intervening layer may include exposing a portion of an upper surface of the substrate and forming the intervening layer to cover the portion of the upper surface of the substrate.

In the method of manufacturing the semiconductor device, the forming of the contact structure may include forming a contact liner along a sidewall of the trench, and forming a contact metal on the contact liner to fill all of the trench.

The foregoing description of embodiments of the present disclosure provides an illustration for the description of the present disclosure. Therefore, the present disclosure is not limited to the above embodiments, and it is apparent that various modifications and changes may be made by those skilled in the art within the technical spirit of the present disclosure, such as implementing the above embodiments in combination.

What is claimed is:

1. A semiconductor device, comprising:
a substrate;
a gate structure over the substrate;
an intervening layer between the gate structure and the substrate;
a contact structure spaced apart from the intervening layer and at least partially penetrating an upper portion of the substrate;
a metal pattern under the contact structure; and
an ohmic pattern at least partially surrounding the metal pattern,
wherein the intervening layer and the ohmic pattern are spaced apart from each other, and
wherein a height of the intervening layer decreases as a distance of the intervening layer from the gate structure increases.

2. The semiconductor device of claim 1, wherein the intervening layer comprises silicon germanium (SiGe).

3. The semiconductor device of claim 1, wherein the metal pattern comprises cobalt (Co), and
wherein the ohmic pattern comprises cobalt-silicide (Co-Si).

4. The semiconductor device of claim 1, wherein an upper surface of the substrate comprises a curved surface, and
wherein an upper surface of the intervening layer comprises another curved surface.

5. The semiconductor device of claim 1, wherein the contact structure comprises a contact metal and a contact liner,
wherein the contact metal comprises a conductive material, and
wherein the contact liner comprises titanium nitride (TiN).

6. The semiconductor device of claim 5, further comprising:
an insulating layer on the substrate, the intervening layer, and the gate structure,
wherein the contact liner is interposed between the contact metal and the substrate, and between the contact metal and the insulating layer.

7. The semiconductor device of claim 1, wherein an area of an upper surface of the intervening layer is larger than an area of a lower surface of the gate structure.

8. The semiconductor device of claim 1, wherein a level of a lowermost portion of the gate structure is higher than a level of an uppermost portion of the metal pattern.

9. A semiconductor device, comprising:
a substrate;
a gate structure over the substrate;
an intervening layer interposed between the gate structure and the substrate;
a contact structure spaced apart from the intervening layer and at least partially penetrating an upper portion of the substrate;
a metal pattern under the contact structure; and
an ohmic pattern at least partially surrounding the metal pattern,
wherein the intervening layer and the ohmic pattern are spaced apart from each other,
wherein an upper surface of the substrate comprises a curved surface, and
wherein an upper surface of the intervening layer comprises another curved surface.

10. The semiconductor device of claim 9, wherein a height of the intervening layer decreases as a distance of the intervening layer from the gate structure increases.

11. The semiconductor device of claim 9, wherein the intervening layer comprises silicon germanium (SiGe).

12. The semiconductor device of claim 9, wherein the metal pattern comprises cobalt (Co), and
wherein the ohmic pattern comprises cobalt-silicide (Co-Si).

13. The semiconductor device of claim 9, wherein the contact structure comprises a contact metal and a contact liner,
wherein the contact metal comprises a conductive material, and
wherein the contact liner comprises titanium nitride (TiN).

14. The semiconductor device of claim 9, further comprising:
an insulating layer on the substrate, the intervening layer and the gate structure,
wherein the contact structure is in contact with the insulating layer and the substrate.

15. The semiconductor device of claim 9, wherein an area of an upper surface of the intervening layer is larger than an area of a lower surface of the gate structure.

16. The semiconductor device of claim 9, wherein a cross-sectional area of the metal pattern is smaller than a cross-sectional area of the ohmic pattern.

17. A semiconductor device, comprising:
a substrate comprising an active region;
a gate structure on the active region, the gate structure comprising a first gate capping pattern, a gate electrode on the first gate capping pattern, and a second gate capping pattern on the gate electrode;
an intervening layer interposed between the gate structure and the substrate;
a contact structure spaced apart from the intervening layer and at least partially penetrating an upper portion of the substrate;
a metal pattern under the contact structure; and
an ohmic pattern at least partially surrounding the metal pattern,
wherein the intervening layer and the ohmic pattern are spaced apart from each other,
wherein an upper surface of the substrate comprises a curved surface, and
wherein an upper surface of the intervening layer comprises another curved surface.

18. The semiconductor device of claim 17, wherein the intervening layer comprises silicon germanium (SiGe),
wherein the metal pattern comprises cobalt (Co), and
wherein the ohmic pattern comprises cobalt-silicide (Co-Si).

19. The semiconductor device of claim 17, wherein the contact structure comprises a contact metal and a contact liner,
wherein the contact metal comprises a conductive material, and
wherein the contact liner comprises titanium nitride (TiN).

20. The semiconductor device of claim 17, further comprising:
an insulating layer on the substrate, the intervening layer and the gate structure,
wherein the contact structure is in contact with the insulating layer and the substrate.
